(19) United States
(12) Patent Application Publication
(10) Pub. No.: US 2011/0315980 A1
(43) Pub. Date: Dec. 29, 2011

(54) Thin Film Transistor and Method of Manufacturing the Same

(76) Inventor: Jae Ho Kim, Yongin-Si (KR)

(21) Appl. No.: 13/165,332

(22) Filed: Jun. 21, 2011

(30) Foreign Application Priority Data
Jun. 23, 2010 (KR) 10-2010-0059456

(51) Int. Cl. H01L 29/786; H01L 21/365

(52) U.S. Cl. 257/43; 438/104; 257/E29.296; 257/E21.463

(57) ABSTRACT

Provided are a Thin Film Transistor (TFT) and a method of manufacturing the same. The TFT includes a gate electrode; a source electrode and a drain electrode spaced from the gate electrode in a vertical direction and spaced from each other in a horizontal direction; a gate insulation layer disposed between the gate electrode and the source and drain electrodes; and an active layer disposed between the gate insulation layer and the source and drain electrodes. The active layer is formed of a conductive oxide layer and comprises at least two layers having different conductivities according to an impurity doped into the conductive oxide layer.

### CROSS-REFERENCE TO RELATED APPLICATION

This application claims priority to Korean Patent Application No. 10-2010-0059456 filed on Jun. 23, 2010 and all the benefits accruing therefrom under 35 U.S.C. §119, the contents of which are incorporated by reference in their entirety.

### BACKGROUND

The present disclosure relates to a Thin Film Transistor (TFT) and a method of manufacturing the same, and more particularly, to a TFT using a conductive oxide layer, which includes Zinc Oxide, as an active layer and a method of manufacturing the same.

A TFT is used as a circuit for driving each pixel separately in a Liquid Crystal Display (LCD) or an organic Electro Luminescence (EL) display. The TFT is formed simultaneously with a gate line and a data line in a bottom substrate of a display device. That is, the TFT includes a gate electrode (which is a portion of the gate line), an active layer used as a channel, a source electrode and a drain electrode (which are portions of the data line), and a gate insulation layer.

The active layer of the TFT serves as a channel region between the gate electrode and the source/drain electrode and is formed of amorphous silicon or crystalline silicon. However, since a TFT substrate using silicon requires a glass substrate, it is heavy and is not easily bent. Thus, the TFT substrate may not be used for a flexible display device. To resolve this, many studies have been made on a metal oxide material recently. Additionally, a crystalline layer having a high carrier concentration and excellent electrical conductivity may be applied to the active layer in order to improve mobility, i.e., to realize a high-speed device.

Studies for a ZnO layer using a metal oxide are actively in progress. In relation to the ZnO layer, crystal growth easily occurs at a low temperature and ZnO is known as an excellent material for obtaining high carrier concentration and mobility. However, when the ZnO layer is exposed to the air, its film quality is unstable and thus, stability of a TFT is deteriorated. Accordingly, in order to improve the film quality of the ZnO layer, researches for improving stability of a TFT by inducing an amorphous ZnO layer after doping the ZnO layer with In, Ga, and Sn have been actively in progress.

### SUMMARY

The present disclosure provides a Thin Film Transistor (TFT) using a conductive oxide layer, which has high mobility and excellent stability, as an active layer and a method of manufacturing the same.

The present disclosure also provides a TFT having high mobility and excellent mobility, which is obtained by forming a conductive oxide layer of two layers having different conductivities and using the conductive oxide layer as an active layer, and a method of manufacturing the same.

In accordance with an exemplary embodiment, Thin Film Transistor (TFT) includes: a gate electrode; a source electrode and a drain electrode spaced from the gate electrode in a vertical direction and spaced from each other in a horizontal direction; a gate insulation layer disposed between the gate electrode and the source and drain electrodes; and an active layer disposed between the gate insulation layer and the source and drain electrodes, wherein the active layer is formed of a conductive oxide layer and includes at least two layers having different conductivities according to an impurity doped into the conductive oxide layer.

The active layer may be formed of a Zinc Oxide (ZnO) having different compositions in a thickness direction.

The active layer may include a front channel region having high conductivity and at least one of a bulk region and a back channel region having a lower conductivity than the front channel region.

The front channel region may be formed by doping the conductive oxide layer with In and Ga, Hf and In, or In.

The bulk region may be formed of a metal oxide layer undoped with an impurity.

The back channel region may be formed by doping the metal oxide layer with Ga, Hf, Sn, and Al.

The front channel region may be formed at a side of the gate electrode and the bulk region or the back channel region may be formed at a side of the source and drain electrodes.

The front channel region may be formed at a side of the gate electrode; the back channel region may be formed at a side of the source and drain electrodes; and the bulk region may be formed between the front channel region and the back channel region.

In accordance with another exemplary embodiment, a method of manufacturing a TFT includes: preparing a substrate; forming a gate electrode and source and drain electrodes on the substrate to be spaced from each other in a vertical direction; forming a gate insulation layer between the gate electrode and the source and drain electrodes; and forming an active layer between the gate insulation layer and the source and drain electrodes, wherein the active layer is formed of a conductive oxide layer and includes at least two layers having different conductivities according to an impurity doped into the conductive oxide layer.

The active layer may include a front channel region having high conductivity and at least one of a bulk region and a back channel region having a lower conductivity than the front channel region.

The front channel region, the bulk region, and the back channel region may be formed in-situ.

The front channel region may be formed through Atomic Layer Deposition (ALD); the bulk region may be formed through Chemical Vapor Deposition (CVD); and the back channel region may be formed through ALD or CVD.

### BRIEF DESCRIPTION OF THE DRAWINGS

Exemplary embodiments can be understood in more detail from the following description taken in conjunction with the accompanying drawings, in which:

FIG. 1 is a sectional view of a Thin Film Transistor (TFT) in accordance with an exemplary embodiment;

FIG. 2 is a sectional view of a TFT in accordance with a modification of an exemplary embodiment;

FIG. 3 is a sectional view of a TFT in accordance with another exemplary embodiment;

FIG. 4 is a sectional view of a TFT in accordance with a modification of another exemplary embodiment;

FIG. 5 is a sectional view of a TFT in accordance with still another exemplary embodiment;

FIG. 6 is a sectional view of a TFT in accordance with a modification of still another exemplary embodiment; and

FIGS. 7 through 10 are sequential sectional views illustrating a method of manufacturing a TFT in accordance with an exemplary embodiment.

### DETAILED DESCRIPTION OF EMBODIMENTS

Hereinafter, specific embodiments will be described in detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. In the figures, the dimensions of layers and regions are exaggerated for clarity of illustration. Like reference numerals refer to like elements throughout. It will also be understood that when a layer, a film, a region or a plate is referred to as being ‘on’ another one, it can be directly on the other one, or one or more intervening layers, films, regions or plates may also be present. Further, it will be understood that when a layer, a film, a region or a plate is referred to as being ‘under’ another one, it can be directly under the other one, and one or more intervening layers, films, regions or plates may also be present. In addition, it will also be understood that when a layer, a film, a region or a plate is referred to as being ‘between’ two layers, films, regions or plates, it can be the only layer, film, region or plate between the two layers, films, regions or plates, or one or more intervening layers, films, regions or plates may also be present.

FIG. 1 is a sectional view of a Thin Film Transistor (TFT) in accordance with an exemplary embodiment. The TFT is a bottom gate TFT.

Referring to FIG. 1, the TFT includes a gate electrode 110 on a substrate 100, a gate insulation layer 120 on the gate electrode 110, an active layer 130 on the gate insulation layer 120, and a source electrode 140a and a drain electrode 140b mutually spaced on the active layer 130.

The substrate 100 may be a transparent substrate. For example, a silicon substrate and a glass substrate may be used for the substrate 100 or when a flexible display is realized, a plastic substrate (such as PE, PES, PET, and PEN) may be used for the substrate 100. Additionally, the substrate 100 may be a reflective substrate (for example, a metal substrate). The metal substrate may be formed of stainless steel, Ti, Mo, or a combination thereof. Meanwhile, when the metal substrate is used as the substrate 100, an insulation layer may be formed on the metal substrate. This prevents a short circuit between the metal substrate and the gate electrode 110 and prevents metal atoms from diffusing from the metal substrate. A material including one of SiO₂, SiN, Al₂O₃, and combinations thereof may be used as the insulation layer. In addition, an inorganic material including one of TiN, TiAlN, SiC and combinations thereof may be used as a diffusion prevention layer below the insulation layer.

The gate electrode 110 may be formed of a conductive material and, for example, may be formed of an alloy including one of Al, Nd, Ag, Cr, Ti, Ta, Mo, Cu, and combinations thereof. Additionally, the gate electrode 110 may include a single layer or a multi layer including a plurality of metal layers. That is, the multi layer may be a double layer including a metal layer of Cr, Ti, Ta, or Mo having excellent physical and chemical properties and an Al, Ag, or Cu based metal layer having small resistivity.

The gate insulation layer 120 may be disposed at least on the gate electrode 110. That is, the gate insulation layer 120 may be disposed a top and a side of the gate electrode 110 on the substrate 100. The gate insulation layer 120 has an excellent adhesion with respect to metal material and may include at least one insulation layer including SiO₂, SiN, Al₂O₃, or ZrO₂, all of which have an excellent adhesion and dielectric voltage withstand with respect to metal material.

The active layer 130 is disposed on the gate insulation layer 120 and at least a portion of the active layer 130 overlaps the gate electrode 110. The active layer 130 may be formed of a conductive oxide layer including a ZnO layer. Additionally, the active layer 130 includes a stacked front channel region 130a and back channel region 130b. Here, the front channel region 130a is a portion of the active layer 130 adjacent to the gate electrode 110 and has a predetermined thickness. The back channel region 130b is the remaining portion of the active layer 130. That is, once (+) voltage is applied to the gate electrode 110, (−) charges accumulate on a portion of the active layer 130 on the gate insulation layer 120 to form a front channel and charge mobility becomes excellent as current flows well through the front channel. Accordingly, the front channel region 130a is formed of materials having excellent mobility, i.e., materials having excellent conductivity. On the contrary, once (−) voltage is applied to the gate electrode 110, (−) charges accumulate on a portion of the active layer 130 below the source electrode 140a and the drain electrode 140b. Therefore, the back channel region 130b may be formed of materials for preventing charge transfer, i.e., materials having a lower conductivity than the front channel region 130a.

In order to form the active layer 130 including the front channel region 130a and the back channel region 130b, respectively different impurities are doped into a conductive oxide layer. That is, the active layer 130 includes conductive oxide layers having different compositions in a thickness direction. For example, when the active layer 130 may be formed of ZnO, the front channel region 130a may be doped with In and Ga, Hf and In, or In and the back channel region 130b may be doped with Ga or Hf. Accordingly, the front channel region 130a may be formed of ZnO doped with In and Ga (i.e., IGZO), ZnO doped with Hf and In (i.e., HIZO), or ZnO doped with In (i.e., IZO). Moreover, the back channel region 130b may be formed of ZnO doped with Ga (i.e., GZO) or ZnO doped with Hf (i.e., HZO).

Since In and Ga, In and Hf, or In is doped into the front channel region 130a, the electron orbits thereof overlap the outermost electron orbit of ZnO so that electrical conduction occurs due to a band conduction mechanism. As a result of this, charge mobility can be improved. Additionally, since the impurities are doped into a region to form the front channel region 130a, an amorphous phase is induced so that a TFT having excellent uniformity can be manufactured. This front channel region 130a may have a thickness of approximately 5 Å to approximately 50 Å and may be formed through an Atomic Layer Deposition (ALD) process.

Meanwhile, the back channel region 130b is formed being doped with Hf or Ga so that an amorphous phase may be induced and also the number of charges may be adjusted. That is, since charges of a ZnO layer may occur mainly due to oxygen deficiency and it is difficult to appropriately control the number of charges only with an adjustment of oxygen concentration, Ga (i.e., a Group III element) or Hf (i.e., a Group IV element) is doped into a region to appropriately control the number of charges. Meanwhile, Sn or Al instead of Ga or Hf may be doped into a region to form the back channel region 130b. Additionally, the back channel region 130b may have a thickness of approximately 200 Å to approximately 300 Å and may be formed through a Chemical Vapor Deposition (CVD) process to achieve fast deposition.

The source electrode 140a and the drain electrode 140b are disposed on the active layer 130 and partially overlap the gate electrode 110 so that they are mutually spaced from each other with the gate electrode 110 therebetween. The source electrode 140a and the drain electrode 140b may be formed through the same material and process and may include a conductive material (for example, one of metals including Al, Nd, Ag, Cr, Ti, Ta, and Mo and alloys thereof). That is, the source electrode 140a and the drain electrode 140b may be formed of the same or different material than the gate electrode 110. Furthermore, the source electrode 140a and the drain electrode 104b may be formed of a single layer or a multi layer including a plurality of metal layers.

As mentioned above, in relation to the TFT, the front channel region 130a is formed by doping a metal oxide with In and Ga, Hf and In, or In and the back channel region 130a is formed by doping a metal oxide with Ga or Hf, thereby forming the active layer 130. Accordingly, a high speed device can be realized by forming the front channel region 130a with excellent mobility and electrical conductivity due to high charge concentration and its stability can be improved by forming the back channel region 130b with an amorphous phase. That is, since the active layer 130 includes the stacked front channel region 130a and back channel region 130b doped with respectively different impurities, a high speed and stable TFT can be manufactured.

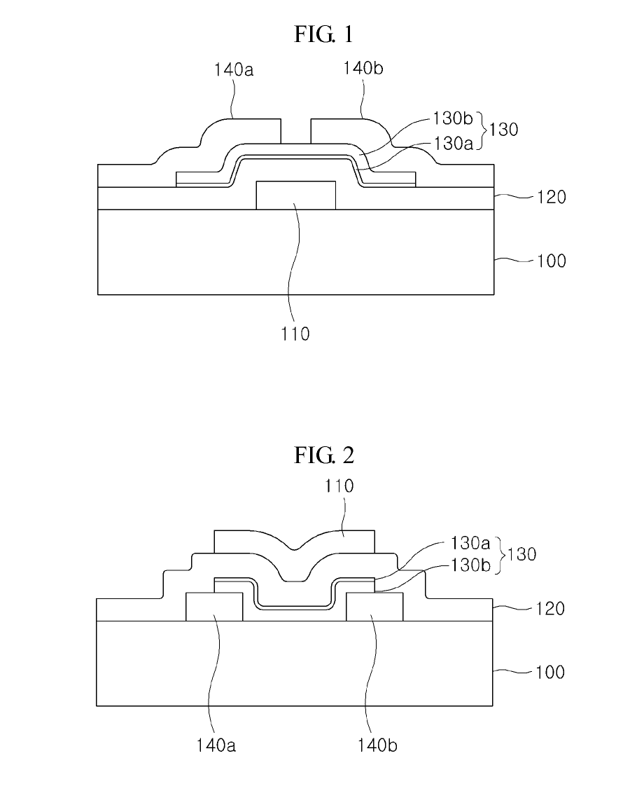

FIG. 2 is a sectional view of a TFT in accordance with a modification of an exemplary embodiment. The TFT is a staggered type top gate TFT.

Referring to FIG. 2, the TFT includes a source electrode 140a and a drain electrode 140b mutually spaced on a substrate 100, an active layer 130 covering the substrate 100, which is exposed to a space between the source electrode 140a and the drain electrode 140b, and portions thereof, and a gate insulation layer 120 and a gate electrode 110 on the active layer 130. Here, the active layer 130 includes a front channel region 130a and a back channel region 130b. The front channel region 130b is formed at the side of the gate electrode 110 and the back channel region 130b is formed at the side of the source electrode 140a and the drain electrode 140b. Accordingly, the back channel region 130b and the front channel region 130a are stacked to form the active layer 130.

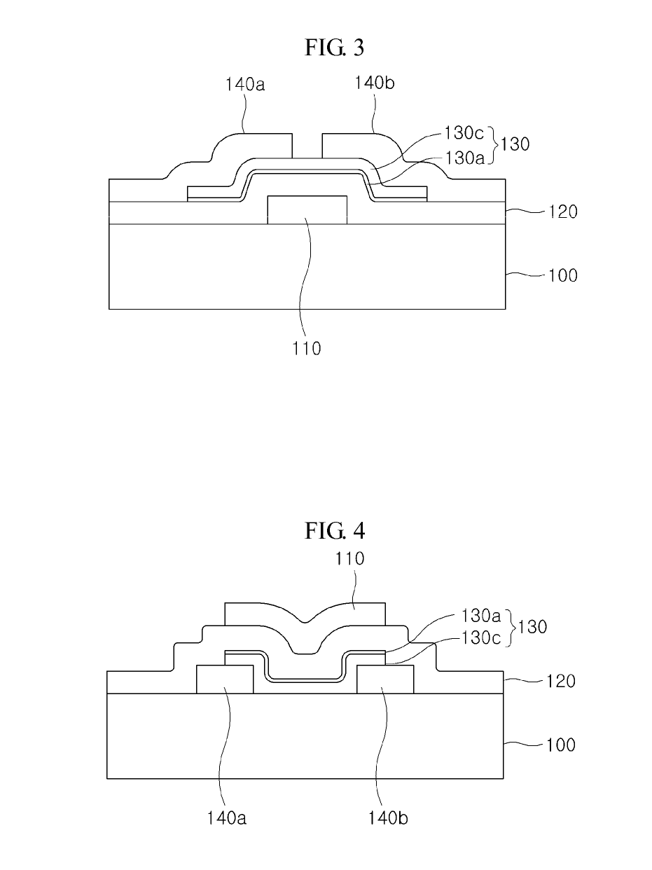

FIG. 3 is a sectional view of a TFT in accordance with another exemplary embodiment. The TFT is a bottom gate TFT.

Referring to FIG. 3, the TFT includes a gate electrode 110 on a substrate 100, a gate insulation layer 120 on the gate electrode 110, an active layer 130 on the gate insulation layer 120, and a source electrode 140a and a drain electrode 140b mutually spaced on the active layer 130. The active layer 130 includes a stacked front channel region 130a and bulk region 130c.

The active layer 130 is disposed on the gate insulation layer 120 and at least a portion of the active layer 130 is disposed to overlap the gate electrode 110. The active layer 130 may be formed of a conductive oxide layer including a ZnO layer. Additionally, the active layer 130 is formed by stacking the front channel region 130a and the bulk region 130c. Here, the front channel region 130a is a portion of the active layer 130 adjacent to the gate electrode 110 and has a predetermined thickness and the bulk region 130c is the remaining portion of the active layer 130. The front channel region 130a improves charge mobility and the bulk region 130c improves stability. For this, the bulk region 130c may be formed with an amorphous phase, for example.

The bulk region 130c may be formed of a conductive oxide layer of ZnO. That is, the bulk region 130c may be formed of a conductive oxide layer undoped with an impurity. Accordingly, the bulk region 130c may have a lower conductivity than the front channel region 130a. Additionally, the bulk region 130c may be formed with a thickness of approximately 200 Å to approximately 300 Å through a CVD process and may be formed with an amorphous phase or a crystalline phase.

FIG. 4 is a sectional view of a TFT in accordance with a modification of another exemplary embodiment. The TFT is a staggered type top gate TFT.

Referring to FIG. 4, the TFT includes a source electrode 140a and a drain electrode 140b mutually spaced on a substrate 100, an active layer 130 covering the substrate 100, which is exposed to a space between the source electrode 140a and the drain electrode 140b and portions thereof, and a gate insulation layer 120 and a gate electrode 110 on the active layer 130. Here, the active layer 130 includes a front channel region 130a and a bulk region 130c. The front channel region 130a is formed at the side of the gate electrode 110 and the bulk region 130c is formed at the source electrode 140a and the drain electrode 140b. Accordingly, the bulk region 130c and the front channel region 130a are stacked to form the active layer 130.

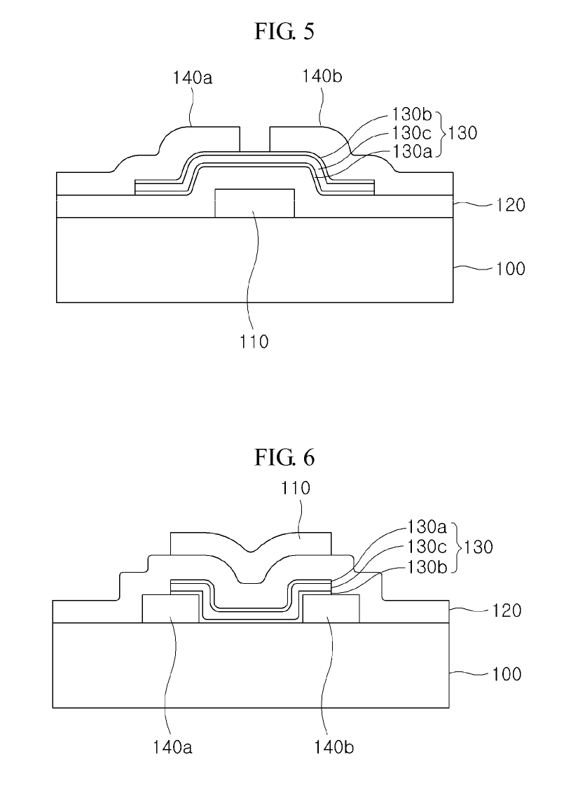

FIG. 5 is a sectional view of a TFT in accordance with still another exemplary embodiment. The TFT includes a gate electrode 110 on a substrate 100, a gate insulation layer 120 on the gate electrode 110, a front channel region 130a on the gate insulation layer 120, an active layer 130 including a bulk region 130c and a back channel region 130b, and a source electrode 140a and a drain electrode 140b mutually spaced on the active layer 130.

The active layer 130 is disposed on the gate insulation layer 120 and at least a portion of the active layer 130 overlaps the gate electrode 110. The active layer 130 may be formed of a conductive oxide layer including a ZnO layer. Additionally, the active layer 130 is formed by stacking the front channel region 130a, the bulk region 130c, and the back channel region 130b. Here, the front channel region 130a is a portion of the active layer 130 adjacent to the gate electrode 110 and has a predetermined thickness. The back channel region 130b is a portion of the active layer 130 adjacent to the source electrode 140a and the drain electrode 140b and has a predetermined thickness. Additionally, the bulk region 130c is disposed between the front channel region 130a and the bulk region 130b and also, the remaining portion of the active layer 130 (i.e., except for the bulk region 130c and the front channel region 130a) becomes the bulk region 130b.

In order to form the active layer 130 including the front channel region 130a, the bulk region 130c, and the back channel region 130b, the front channel region 130a and the back channel region 130b are formed by doping a conductive oxide layer with respectively different impurities and the bulk region 130c may be formed of the conductive oxide layer undoped with the impurities. For example, the active layer 130 may be formed of ZnO; the front channel region 130a may be formed being doped with In and Ga, Hf and In, or In; the bulk region 130c may be formed being undoped with an impurity; and the back channel region 130b may be formed being doped with Ga or Hf. Here, the front channel region 130a improves charge mobility and the back channel region 130b prevents charge transfer. Additionally, the bulk region 130c may improve stability and for this, may be formed with an amorphous phase. Accordingly, the front channel region 130a has a higher conductivity than the bulk region 130c and also, the bulk region 130c has a higher conductivity than the back channel region 130b.

Meanwhile, the front channel region 130a may be formed with a thickness of approximately 5 Å and approximately 50 Å through an ALD process. Additionally, the bulk region 130c may be formed with a thickness of approximately 200 Å and approximately 300 Å through a CVD process and may be formed with an amorphous phase or a crystalline phase. Additionally, the back channel region 130b may be formed with a thickness of approximately 5 Å and approximately 50 Å through an ALD process or a CVD process and may be formed with an amorphous phase.

FIG. 6 is a sectional view of a TFT in accordance with a modification of still another exemplary embodiment. The TFT is a staggered type top gate TFT. In the TFT, an active layer 130 includes a stacked front channel region 130a, bulk region 130c, and a back channel region 130b.

Referring to FIG. 6, the TFT includes a source electrode 140a and a drain electrode 140b mutually spaced on a substrate 100, the back channel region 130b covering the substrate 100, which is exposed to a space between the source electrode 140a and the drain electrode 140b, and portions thereof, the active layer 130 including the stacked bulk region 130c and front channel region 130a, and a gate insulation layer 120 and a gate electrode 110 on the active layer 130. That is, in relation to the top gate TFT, since the gate electrode 110 is disposed at the top and the source electrode 140a and the drain electrode 140b are disposed at the bottom, the bulk region 130c and the front channel region 130a are disposed on the back channel region 130b in the active layer 130.

Meanwhile, the TFT may be used as a driving circuit for driving each pixel in a display device such as a Liquid Crystal Display (LCD) and an organic Electro Luminescence (EL) display. That is, the TFT is formed in each pixel in a display panel having a plurality of pixels in a matrix. Each pixel is selected through the TFT and then data for displaying an image are delivered to the selected pixel.

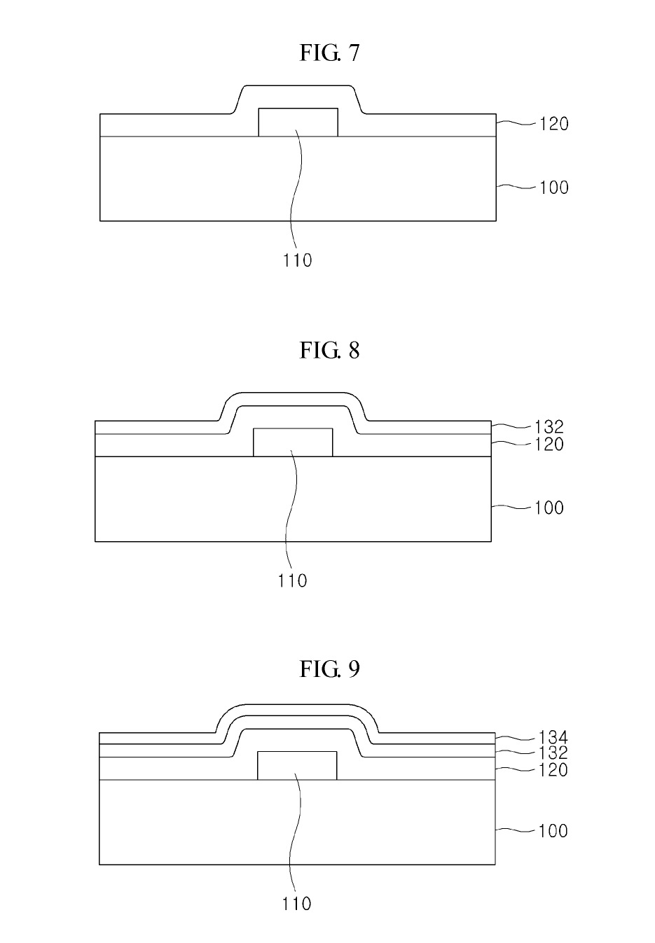

FIGS. 7 through 10 are sequential sectional views illustrating a method of manufacturing a TFT in accordance with an exemplary embodiment. The TFT is a bottom gate TFT.

Referring to FIG. 7, a gate electrode 110 is formed on a predetermined region of a substrate 100 and then a gate insulation layer 120 is formed an entire upper portion including the gate electrode 110. In order to form the gate electrode 110, a first conductive layer may be formed on the substrate 100 through a CVD process and then is patterned through a photo and etching process using a predetermined mask. Here, the first conductive layer may be formed of one of a metal, a metallic alloy, a metal oxide, a transparent conductive layer and combinations thereof Additionally, the first conductive layer may be formed of a plurality of layers in consideration of conductivity and resistance properties. Moreover, the gate insulation layer 120 may be formed on an entire top portion including the gate electrode 110 and may be formed of an inorganic insulation material including an oxide and/or a nitride or an organic insulation material.

Referring to FIG. 8, a first metal oxide semiconductor layer 132 is formed on an entire top portion including the gate insulation layer 120. The first metal oxide semiconductor layer 132 may be formed through an ALD process. Here, the first metal oxide semiconductor layer 132 may be formed with an inflow of a metal precursor, a reaction gas, and a first impurity gas. The metal precursor may use Zn and the reaction gas may use a gas including oxygen. Additionally, the first impurity gas may use one of a mixed gas of In and Ga, a mixed gas of Hf and In, and In gas. Additionally, in order to form the first metal oxide semiconductor layer 132 through an ALD process, supplying and purging of the metal precursor and the first impurity gas and supplying and purging of the reaction gas are repeated several times. The first metal oxide semiconductor layer 132 may be formed with a thickness of approximately 5 Å and approximately 50 Å.

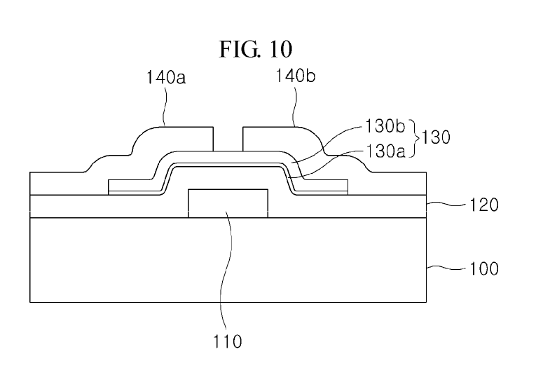

Referring to FIG. 9, a second metal oxide semiconductor layer 134 is formed on the first metal oxide semiconductor layer 132. The second metal oxide semiconductor layer 134 may be formed with an inflow of a metal precursor, a reaction gas, and a second impurity gas. The metal precursor may use Zn and the reaction gas may use a gas including oxygen. Additionally, the second impurity gas may use one of In, Ga, Sn, and Al. That is, the second metal oxide semiconductor layer 134 may use the same metal precursor and reaction gas as the first metal oxide semiconductor layer 132 and may use a different impurity gas than the first metal oxide semiconductor layer 132. Additionally, the second metal oxide semiconductor layer 134 may be formed through a CVD process to improve a process speed. That is, the metal precursor, the reaction gas, and the second impurity gas are simultaneously supplied to from the second metal oxide semiconductor layer 134 on the first metal oxide semiconductor layer 132. The second metal oxide semiconductor layer 134 may be formed with a thickness of approximately 200 Å to approximately 300 Å. Here, the first and second metal oxide semiconductor layers 132 and 134 may be formed in situ in the same reaction chamber. For this, the reaction chamber may be a chamber where an ALD process and a CVD process are possible. For example, the reaction chamber may include a rotatable susceptor on which a plurality of substrates 100 are mounted, and at least four injectors for separately injecting a metal precursor and impurity gas, a purge gas, a reaction gas, and a purge gas. Thus, an atomic layer is deposited using a gas injected from each injector while the susceptor rotates and a CVD process is performed, as at least two injectors separately inject a metal precursor and impurity gas, and a reaction gas.

Referring to FIG. 10, the first and second metal oxide semiconductor layers 132 and 134 are patterned to cover the gate electrode 110, so that the active layer 130 is formed. Accordingly, the active layer 130 has a structure where a front channel region 130a and a back channel region 130b are stacked. Next, a second conductive layer is formed on the active layer 130 and then is patterned through a photo and etching process using a predetermined mask, thereby forming a source electrode 140a and a drain electrode 140b. Here, the second conductive layer may be formed of one of a metal, a metallic alloy, a metal oxide, a transparent conductive layer, and combinations thereof, through a CVD process. Additionally, the second conductive layer may include a plurality of layers in consideration of conductivity and resistance properties. Meanwhile, the source electrode 140a and the drain electrode 140b are formed to partially overlap the top of the gate electrode 110 and to be spaced from each other on the gate electrode 110.

Additionally, the above exemplary embodiment is described with a case that the first conductive layer for the gate electrode 110, the gate insulation layer 120, the second metal oxide semiconductor layer 134 for the active layer 130, and the second conductive layer for the source and drain electrodes 140a and 140b are formed through a CVD process. However, besides the CVD process, a Physical Vapor Deposition (PVD) process may be used. That is, a layer may be formed through sputtering, a vacuum deposition process, or ion plating. At this point, if the layer is formed through the sputtering, the above structures may be formed through a sputtering process with a sputtering mask (i.e., a shadow mask), without a photo and etching process with a predetermined mask. Additionally, besides a CVD or PVD process, as various coating methods including imprinting (such as spin coating, deep coating, and nano imprinting), stamping, printing, or transfer printing may be used for coating by using a colloidal solution of dispersed fine particles or a liquid sol-gel including precursors. Additionally, coating may be performed through an ALD process or a Pulsed Laser Deposition (PLD) process.

According to an exemplary embodiment, an active layer is formed with at least two layer having respectively different conductivities. According to whether an impurity is doped into a conductive oxide layer or types of impurities doped, a front channel region is included and at least one of a bulk region and a back channel is included, in order to form an active region.

According to an exemplary embodiment, a front channel region has a more excellent conductivity than a bulk region and a back channel region and is formed adjacent to a gate electrode, thereby improving the operating speed of a TFT.

Additionally, the bulk region and the channel region improve stability and prevent charge transfer and are formed adjacent to source and drain electrodes. Therefore, stability of a TFT can be improved.

As a result, since an active layer is formed with at least two layers having respectively different conductivities, a high-speed operation of a device can be achieved and its stability can be improved.

Although the film transistor and the method of manufacturing the same have been described with reference to the specific embodiments, they are not limited thereto. Therefore, it will be readily understood by those skilled in the art that various modifications and changes can be made thereto without departing from the spirit and scope of the present invention defined by the appended claims.

What is claimed is:

1. A thin film transistor (TFT) comprising:
a gate electrode;
a source electrode and a drain electrode spaced from the gate electrode in a vertical direction and spaced from each other in a horizontal direction;
a gate insulation layer between the gate electrode and the source and drain electrodes; and
an active layer between the gate insulation layer and the source and drain electrodes,
wherein the active layer comprises a first conductive oxide layer having a first conductivity and a second conductive oxide layer having a second conductivity different from said first conductivity, said first and second conductivities corresponding to an impurity in the respective conductive oxide layer.

2. The TFT of claim 1, wherein the first conductive oxide layer comprises zinc oxide (ZnO) having a first composition and the second conductive oxide layer comprises zinc oxide (ZnO) having a second composition different from the first composition.

3. The TFT of claim 1, wherein the first conductive oxide layer comprises a front channel region having relatively high conductivity and the second conductive oxide layer comprises at least one of a bulk region and a back channel region having a lower conductivity than the front channel region.

4. The TFT of claim 3, wherein the front channel region comprises a conductive oxide doped with In.

5. The TFT of claim 4, wherein the front channel region comprises the conductive oxide doped with In and either Ga or Hf.

6. The TFT of claim 3, wherein the second conductive oxide layer comprises the bulk region.

7. The TFT of claim 6, wherein the bulk region consists essentially of an undoped metal oxide layer.

8. The TFT of claim 3, wherein the second conductive oxide layer comprises the back channel region.

9. The TFT of claim 8, wherein the back channel region comprises a metal oxide layer doped with Ga, Hf, Sn, or Al.

10. The TFT of claim 3, wherein the front channel region is at a side of the gate electrode and the bulk region or the back channel region is at a side of the source and drain electrodes.

11. The TFT of claim 3, wherein the second conductive oxide layer comprises the bulk region and the back channel region.

12. The TFT of claim 11, wherein:
the front channel region is at a side of the gate electrode;
the back channel region is at a side of the source and drain electrodes; and
the bulk region is between the front channel region and the back channel region.

13. A method of manufacturing a thin film transistor (TFT), comprising:
forming a gate electrode and source and drain electrodes on a substrate, the gate electrode spaced from the source and drain electrodes in a vertical direction;
forming a gate insulation layer on one of (i) the gate electrode and (ii) the source and drain electrodes; and
forming an active layer on one of (i) the gate insulation layer and (ii) the source and drain electrodes,
wherein the active layer comprises a first conductive oxide layer having a first conductivity and a second conductive oxide layer having a second conductivity different from said first conductivity, said first and second conductivities corresponding to an impurity in the respective conductive oxide layer.

14. The method of claim 13, wherein the first conductive oxide layer comprises a front channel region having a relatively high conductivity and a second conductive oxide layer comprising at least one of a bulk region and a back channel region having a lower conductivity than the front channel region.

15. The method of claim 14, wherein the second conductive oxide layer comprises the bulk region and the back channel region.

16. The method of claim 15, wherein the front channel region, the bulk region, and the back channel region are formed in-situ.

17. The method of claim 15, wherein
the front channel region is formed by Atomic Layer Deposition (ALD);
the bulk region is formed by Chemical Vapor Deposition (CVD); and
the back channel region is formed by ALD or CVD.

18. The method of claim 13, wherein forming the gate electrode and source and drain electrodes, forming the gate insulation layer, and forming the active layer comprises (i) forming the gate electrode on the substrate, (ii) forming the gate insulation layer on the gate electrode, (iii) forming the active layer on the gate insulation layer, and (iv) forming the source and drain electrodes on the active layer.

19. The method of claim 13, wherein forming the gate electrode and source and drain electrodes, forming the gate insulation layer, and forming the active layer comprises (i) forming the source and drain electrodes on the substrate, (ii) forming the active layer gate insulation layer on the source and drain electrodes, (iii) forming the gate insulation layer on the active layer, and (iv) forming the gate electrode on the gate insulation layer.

20. The method of claim 13, wherein the first conductive oxide layer comprises ZnO doped with In, and the second conductive oxide layer comprises undoped ZnO or ZnO doped with Ga, Hf, Sn, or Al.
